(19) United States
(12) Patent Application Publication
(10) Pub. No.: US 2026/0228402 A1
(43) Pub. Date: Aug. 6, 2026

(54) SYSTEM AND METHOD FOR GENERATING SEMICONDUCTOR DEVICE MODELS BASED ON RETARGETED ELECTRICAL CHARACTERISTICS

(71) Applicant: RESEARCH & BUSINESS FOUNDATION SUNGKYUNKWAN UNIVERSITY, Suwon-si (KR)

(72) Inventors: Jong Wook JEON, Suwon-si (KR); Jae Weon KANG, Suwon-si (KR); Sue Yeon KIM, Seoul (KR)

(21) Appl. No.: 19/454,667

(22) Filed: Jan. 21, 2026

(30) Foreign Application Priority Data
Feb. 5, 2025 (KR) 10-2025-0014665
Nov. 19, 2025 (KR) 10-2025-0175489

(51) Int. Cl. G06F 30/32

(52) U.S. Cl. CPC G06F 30/32

(57) ABSTRACT

Provided is a system for generating a semiconductor device model. The system for generating the semiconductor device model includes: an extraction unit for extracting LUT data including input data and output data of an original semiconductor device by simulating the original semiconductor device under various operating conditions, and calculating an electrical characteristic index of the original semiconductor device from the LUT data; a retarget unit for generating retarget LUT data by adjusting the LUT data to satisfy a target electrical characteristic index provided by a user; and an update unit for determining a final semiconductor device model by comparing an operation simulation result of a model based on the retarget LUT data with the target electrical characteristic index.

### BACKGROUND OF THE INVENTION

### 1. Field of the Invention

The present invention relates to a system and a method for generating a semiconductor device model based on a retargeted electrical characteristic.

### 2. Description of the Related Art

As processes become finer and structural complexity increases, electrical characteristics of a semiconductor device significantly vary depending on process conditions, channel lengths, material properties, design goals, and the like even for the same semiconductor device. In order to perform circuit simulation that reflects such various device characteristics, a device model that accurately describes electrical characteristics such as a current, a charge, and capacitance according to input conditions of a device is required.

Conventionally, standard compact models such as a Berkeley short-channel IGFET model (BSIM) and a Phillips SGP model (PSP) have been widely used, and such models express electrical characteristics of a device based on expressions by using parameters that reflect process conditions. However, as process deviations and structural changes, such as an ultra-fine CMOS process, a gate-all-around (GAA) device, an amorphous structure device, and a new device structure, increase significantly, it is difficult to rapidly reconfigure a model to satisfy specific electrical characteristics (e.g., target Vₜₕ, SS, I_{ON}, etc.) required by a circuit designer with only existing compact model parameters.

In addition, the need for various “retargeted models” such as a process corner model, a customized device model for each digital/analog block, and a custom device model that reflects foundry customer requirement specifications (foundry target spec) has been recently increased. However, in order to generate such models, a series of processes of simulating large amounts of device characteristic data, adjusting the data to satisfy desired electrical indexes, and finally converting the data into a form of a simulator-operable model (e.g., a SPICE compact model or a Verilog-A model) is required.

According to the related art, a scheme of manually adjusting model parameters or obtaining data by re-simulating a new device based on TCAD has been mainly used to modify device specifications. However, such a scheme has limitations that the scheme is time-consuming, requires repetitive adjustments, and is difficult to ensure accuracy of a model. In particular, the scheme has inefficiencies due to the need to repeatedly attempt and verify parameters until target electrical characteristics are achieved.

### SUMMARY OF THE INVENTION

One technical object of the present invention is to provide a system and a method for generating a semiconductor device model based on a retargeted electrical characteristic.

Another technical object of the present invention is to provide a system and a method, capable of rapidly constructing a new semiconductor device model that allows main electrical characteristic indexes such as a threshold voltage (Vₜₕ), subthreshold swing (SS), and an on-current (I_{ON}) to vary even without changing process conditions or device structures.

Still another technical object of the present invention is to provide a system and a method, capable of providing significantly greater simplicity and high accuracy as compared to existing schemes that require direct adjustment of parameters of complex physical models, such as BSIM-CMG and BSIM-CMC.

Yet another technical object of the present invention is to provide a system and a method, capable of allowing a user to automatically generate a SPICE model having high reliability by inputting only desired target electrical characteristics.

Technical objects of the present invention are not limited to the technical objects described above.

To achieve the technical objects described above, the present invention provides a system for generating a semiconductor device model.

According to one embodiment, the system for generating the semiconductor device model includes: an extraction unit for extracting LUT data including input data and output data of an original semiconductor device by simulating the original semiconductor device under various operating conditions, and calculating an electrical characteristic index of the original semiconductor device from the LUT data; a retarget unit for generating retarget LUT data by adjusting the LUT data to satisfy a target electrical characteristic index provided by a user; and an update unit for determining a final semiconductor device model by comparing an operation simulation result of a model based on the retarget LUT data with the target electrical characteristic index.

According to one embodiment, the LUT data may include the input data and the output data in a form of a look-up table.

According to one embodiment, the retarget unit may generate the retarget LUT data by adjusting the LUT data such that a threshold voltage (Vₜₕ), a subthreshold swing (SS), and an on-current (I_{ON}) of the electrical characteristic index are equal to a target threshold voltage, target subthreshold swing, and a target on-current of the target electrical characteristic index, respectively.

According to one embodiment, the retarget LUT data may be generated based on a gate-source voltage (V_{GS}) and a drain current (I_{D}) of the LUT data.

According to one embodiment, the retarget LUT data may be generated by horizontally shifting a curve of the drain current according to the gate-source voltage (I_{D}-V_{GS}) of the LUT data such that the threshold voltage of the electrical characteristic index is equal to the target threshold voltage of the target electrical characteristic index.

According to one embodiment, the retarget LUT data may be generated by adjusting an angle of a subthreshold region in a graph of the drain current according to the gate-source voltage (I_{D}-V_{GS}) of the LUT data such that the subthreshold swing of the electrical characteristic index is equal to the target subthreshold swing of the target electrical characteristic index.

According to one embodiment, the retarget LUT data may be generated by adjusting a current level of a saturation region in a graph of the drain current according to the gate-source voltage (I_{D}-V_{GS}) of the LUT data such that the on-current of the electrical characteristic index is equal to the target on-current of the target electrical characteristic index.

According to one embodiment, the retarget LUT data may be generated by adjusting data between a linear region and a saturation region in a graph of the drain current according to the gate-source voltage (I_{D}-V_{GS}) of the LUT data through interpolation.

According to one embodiment, the update unit may determine the model based on the retarget LUT data as the final semiconductor device model when a difference between the operation simulation result of the model based on the retarget LUT data and the target electrical characteristic index is within a reference range.

According to one embodiment, the update unit may request the retarget unit to regenerate the retarget LUT data when the difference between the operation simulation result of the model based on the retarget LUT data and the target electrical characteristic index is outside the reference range.

According to another embodiment, the system for generating the semiconductor device model includes: an extraction unit for extracting LUT data including input data and output data of an original semiconductor device by simulating the original semiconductor device under various operating conditions, calculating an electrical characteristic index of the original semiconductor device from the LUT data, and verifying whether an operation of a model based on the LUT data matches an operation of the original semiconductor device; a retarget unit for generating retarget LUT data by adjusting the LUT data to satisfy a target electrical characteristic index provided by a user; and an update unit for determining a final semiconductor device model by comparing an operation simulation result of a model based on the retarget LUT data with the target electrical characteristic index.

According to another embodiment, simulation of the original semiconductor device and an operation simulation of the model based on the retarget LUT data may be performed through simulation program with integrated circuit emphasis (SPICE).

According to another embodiment, the retarget LUT data may be converted into a Verilog-A-based model and applied to SPICE simulation.

To achieve the technical objects described above, the present invention provides a method for generating a semiconductor device model.

According to one embodiment, the method for generating the semiconductor device model includes: extracting LUT data including input data and output data of an original semiconductor device by simulating the original semiconductor device under various operating conditions; calculating an electrical characteristic index of the original semiconductor device from the LUT data; generating retarget LUT data by adjusting the LUT data to satisfy a target electrical characteristic index provided by a user; and determining a final semiconductor device model by comparing an operation simulation result of a model based on the retarget LUT data with the target electrical characteristic index.

According to one embodiment, the LUT data may include the input data and the output data in a form of a look-up table, and the electrical characteristic index may include a threshold voltage (Vₜₕ), a subthreshold swing (SS), and an on-current (I_{ON}).

According to an embodiment of the present invention, a system for generating a semiconductor device model may automatically generate look-up table (LUT) data that accurately reflects an operation of an original semiconductor device through SPICE-based simulation, so that a new semiconductor device model that allows main electrical characteristic indexes such as a threshold voltage (Vₜₕ), subthreshold swing (SS), and an on-current (I_{ON}) to vary even without changing process conditions or device structures can be rapidly constructed. Accordingly, significantly greater simplicity and high accuracy as compared to existing schemes that require direct adjustment of parameters of complex physical models, such as BSIM-CMG and BSIM-CMC, can be provided, and a user can be allowed to automatically generate a SPICE model having high reliability by inputting only desired target electrical characteristics.

### BRIEF DESCRIPTION OF THE DRAWINGS

FIG. 1 is a view for describing each of components of a system for generating a semiconductor device model according to an embodiment of the present invention.

FIG. 2 is a flowchart for describing a method for generating a semiconductor device model according to an embodiment of the present invention.

FIG. 3 is a view for describing a process of calculating an electrical characteristic index, which is performed by an extraction unit of the system for generating the semiconductor device model according to the embodiment of the present invention.

FIG. 4 is a view for describing a method for calculating an electrical characteristic index.

FIG. 5 is a view for describing a process of generating retarget LUT data, which is performed by a retarget unit of the system for generating the semiconductor device model according to the embodiment of the present invention.

FIG. 6 is a view for comparing I_{DS}-V_{GS} curves of an original device and a retarget device on a linear scale.

FIG. 7 is a graph for comparing the I_{DS}-V_{GS} curves of the original device and the retarget device on a log scale.

FIG. 8 is a graph for comparing Q_{g}-V_{g} curves of the original device and the retarget device.

FIG. 9 is a view for describing a process of automatically generating a SPICE input file (sp file) for extracting an electrical characteristic according to an embodiment of the present invention.

FIG. 10 is a view for describing a process of generating a table file (TBL) for extracting a threshold voltage (Vₜₕ) of an original semiconductor device according to an embodiment of the present invention.

FIG. 11 is a view showing a process of verifying whether LUT data matches a SPICE simulation result according to an embodiment of the present invention.

FIG. 12 is a view showing results of extracting main electrical characteristics (Vₜₕ, SS, and I_{ON}) of the original semiconductor device according to an embodiment of the present invention.

FIG. 13 is a view showing a target electrical characteristic index (retarget value) that is input by a user and a SPICE simulation result obtained accordingly, and error comparison according to an embodiment of the present invention.

FIG. 14 is a view showing a portion of internal implementation of a Verilog-A device model that operates based on retarget LUT data according to an embodiment of the present invention.

FIG. 15 is a view showing results of displaying an I_{D}-V_{GS} curve of a retargeted device model on a linear scale and a log scale according to an embodiment of the present invention.

FIG. 16 is a view for describing a procedural flow of a process for generating a semiconductor device model according to an embodiment of the present invention.

### DETAILED DESCRIPTION OF THE INVENTION

Hereinafter, exemplary embodiments of the present invention will be described in detail with reference to the accompanying drawings. However, the technical idea of the present invention is not limited to the embodiments described herein, but may be embodied in different forms. The embodiments introduced herein are provided to sufficiently deliver the idea of the present invention to those skilled in the art so that the disclosed contents may become thorough and complete.

When it is mentioned in the present disclosure that one element is on another element, it means that one element may be directly formed on another element, or a third element may be interposed between one element and another element. Further, in the drawings, thicknesses of films and regions are exaggerated for effective description of the technical contents.

In addition, although the terms such as first, second, and third have been used to describe various elements in various embodiments of the present disclosure, the elements are not limited by the terms. The terms are used only to distinguish one element from another element. Therefore, an element mentioned as a first element in one embodiment may be mentioned as a second element in another embodiment. The embodiments described and illustrated herein include their complementary embodiments, respectively. Further, the term “and/or” used in the present disclosure is used to include at least one of the elements enumerated before and after the term.

As used herein, an expression in a singular form includes a meaning of a plural form unless the context clearly indicates otherwise. Further, the terms such as “including” and “having” are intended to designate the presence of features, numbers, steps, elements, or combinations thereof described herein, and shall not be construed to preclude any possibility of the presence or addition of one or more other features, numbers, steps, elements, or combinations thereof. In addition, the term “connection” used herein is used to include both indirect and direct connections of a plurality of elements.

Further, in the following description of the present invention, detailed descriptions of known functions or configurations incorporated herein will be omitted when they may make the gist of the present invention unnecessarily unclear.

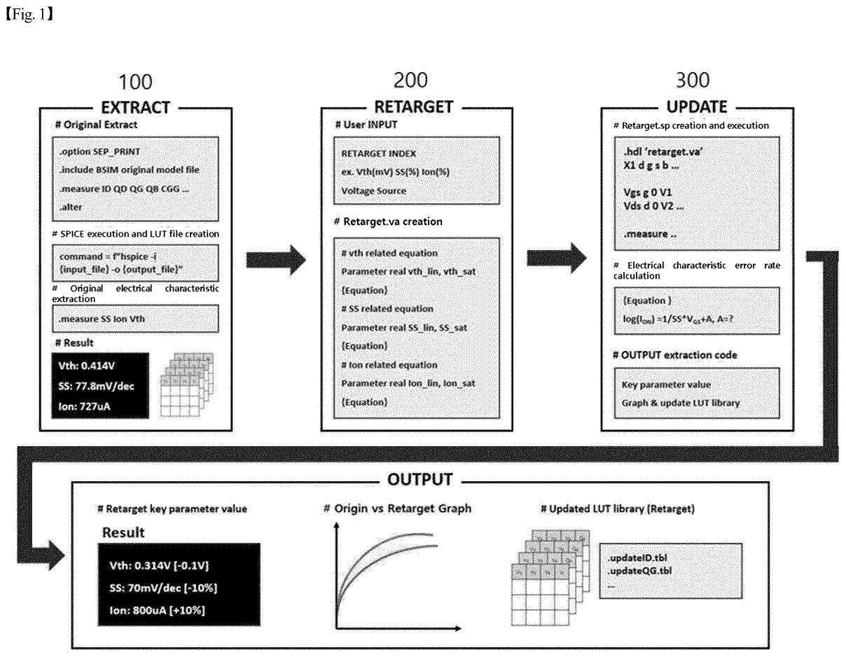

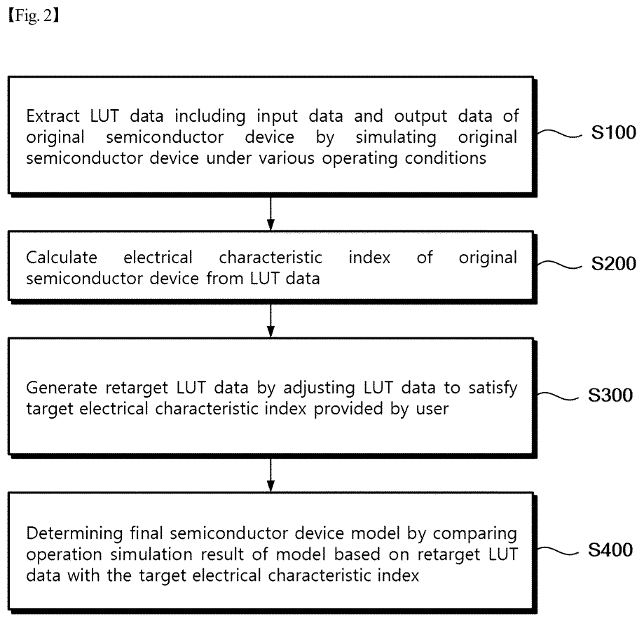

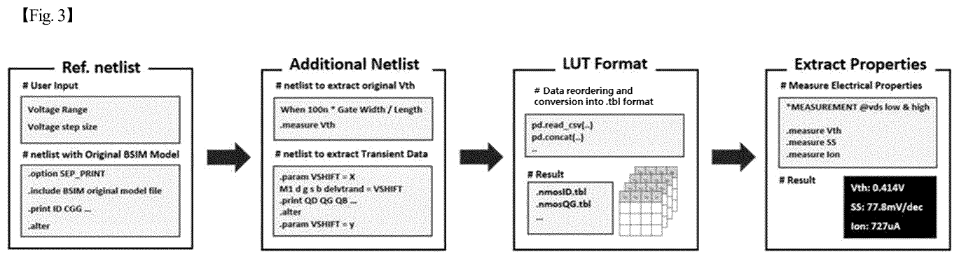

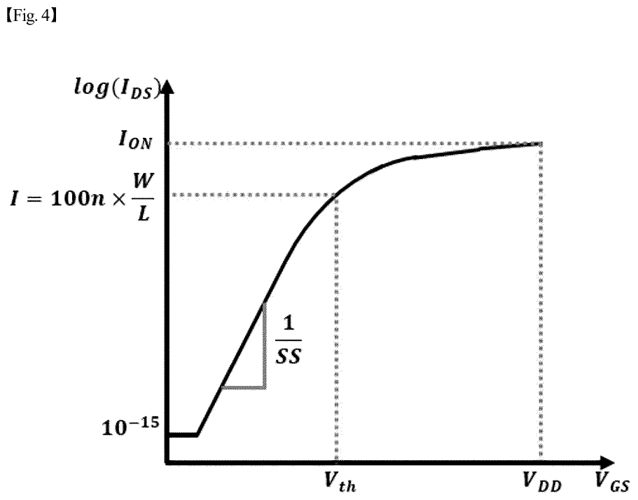

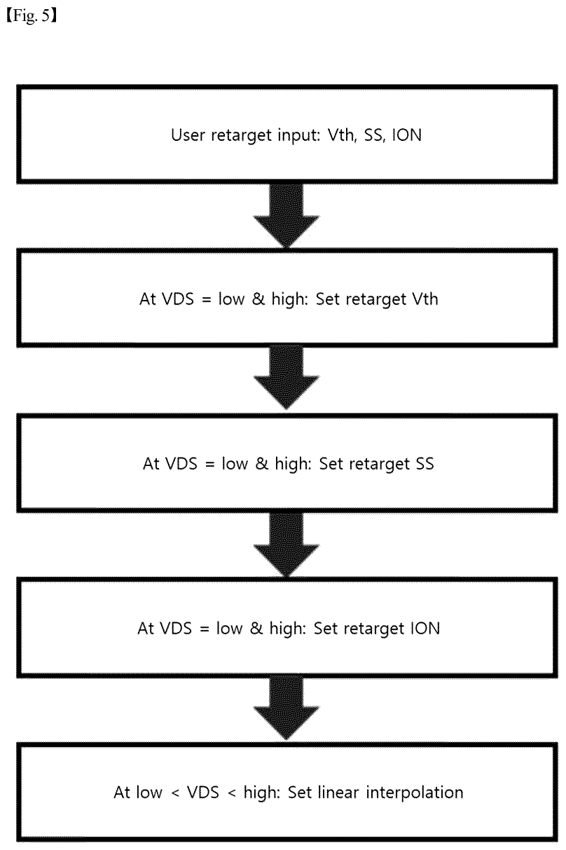

FIG. 1 is a view for describing each of components of a system for generating a semiconductor device model according to an embodiment of the present invention, FIG. 2 is a flowchart for describing a method for generating a semiconductor device model according to an embodiment of the present invention, FIG. 3 is a view for describing a process of calculating an electrical characteristic index, which is performed by an extraction unit of the system for generating the semiconductor device model according to the embodiment of the present invention, FIG. 4 is a view for describing a method for calculating an electrical characteristic index, and FIG. 5 is a view for describing a process of generating retarget LUT data, which is performed by a retarget unit of the system for generating the semiconductor device model according to the embodiment of the present invention.

Referring to FIGS. 1 to 5, according to an embodiment of the present invention, a system for generating a semiconductor device model may include an extraction unit 100, a retarget unit 200, and an update unit 300. In addition, according to an embodiment of the present invention, a method for generating a semiconductor device model may include extracting LUT data (S100), calculating an electrical characteristic index (S200), generating retarget LUT data (S300), and determining a final semiconductor device model (S400). According to one embodiment, the steps S100 and S200 may be performed by the extraction unit 100, the step S300 may be performed by the retarget unit 200, and the step S400 may be performed by the update unit 300. Hereinafter, each of components will be described.

The extraction unit 100 may simulate an operation of a device under various operating conditions to obtain basic electrical characteristics of an original semiconductor device, extract LUT data including input data and output data from a result of the simulation, and calculate an electrical characteristic index of the original semiconductor device from the LUT data. According to one embodiment, the LUT data may include the input data and the output data in the form of a look-up table. According to one embodiment, the electrical characteristic index may include a threshold voltage (Vₜₕ), subthreshold swing (SS), and an on-current (I_{ON}).

In more detail, the extraction unit 100 may load a compact model (e.g., BSIM, PSP, HiSIM, etc.) of the original semiconductor device provided by a user on a simulation environment so as to automatically generate a SPICE-based simulation input file so that an output parameter such as a drain current (I_{D}), a gate charge (Q_{G}), a drain charge (Q_{D}), and gate capacitance (C_{GG}) according to an input condition such as a gate-source voltage (V_{GS}) and a drain-source voltage (V_{DS}) may be collectively calculated.

According to one embodiment, the extraction unit 100 may configure a netlist including a model file of the original semiconductor device, and create a SPICE input file that automatically reflects a simulation sweep range, a voltage interval (step), a measurement instruction (.measure), an output instruction (.print/.save), and the like. Thereafter, a SPICE simulator may be called to execute the input file so that device operation data for various V_{GS}-V_{DS} combinations may be obtained. A simulation result may be saved in a raw output file format such as a printsw file, and the extraction unit 100 may parse the file to extract the LUT data.

The LUT data may be data organized in the form of a table, including a current, a charge, capacitance, and the like output according to the combinations of V_{GS} and V_{DS}, and may be subsequently used as base data for adjusting an electrical characteristic by the retarget unit 200. In addition, the extraction unit 100 may automatically calculate the threshold voltage (Vₜₕ), the subthreshold swing (SS), and the on-current (I_{ON}), which are main electrical characteristic indexes of the original semiconductor device, by using I_{D}-V_{GS} and other curve data sorted with a LUT.

For example, as shown in FIG. 4, the extraction unit 100 may calculate a gate voltage corresponding to a specific reference current from an I_{D}-V_{GS} curve as the threshold voltage (Vₜₕ). In more detail, a gate voltage value when the drain current is 100 nA×gate width (W)/gate length (L) may be calculated as the threshold voltage (Vₜₕ). Alternatively, the extraction unit 100 may calculate the subthreshold swing (SS) by using a gate voltage change required to increase a log current in a subthreshold region of the I_{D}-V_{GS} curve. In more detail, a V_{GS} value at which the current increases 10-fold in the subthreshold region may be calculated as the subthreshold swing (SS). Alternatively, the extraction unit 100 may calculate a drain saturation current under a condition of V_{GS}=V_{DD} as the on-current (I_{ON}).

The electrical characteristic indexes (Vₜₕ, SS, and I_{ON}) calculated as described above may be stored as reference values for the original semiconductor device, and may be used as initial comparison references when the retarget unit 200 adjusts the LUT data to satisfy a target electrical characteristic index. The extraction unit 100 may finally store and provide the LUT data and the electrical characteristic indexes (Vₜₕ, SS, and I_{ON}) so that the retarget unit 200 and the update unit 300 may use the LUT data and the electrical characteristic indexes, which may serve as inputs for subsequent retarget and model update processes.

In addition, according to one embodiment, the extraction unit 100 may further perform a function of verifying whether an operation of a model based on the LUT data matches an operation of the original semiconductor device. In detail, the extraction unit 100 may generate a LUT-based model (e.g., a LUT-based model in the form of Verilog-A) that approximates electrical characteristics of the original semiconductor device by using the LUT data, and may perform SPICE simulation on the LUT-based model under simulation conditions that are identical to simulation conditions applied to the original semiconductor device.

In this case, the extraction unit 100 may compare a simulation result of the original semiconductor device model with a simulation result of the LUT-based model to determine whether the two results match within a predetermined reference range. For example, the extraction unit 100 may compare the electrical characteristic indexes such as the I_{D}-V_{GS} curve, an I_{D}-V_{DS} curve, the threshold voltage (Vₜₕ), the subthreshold swing (SS), and the on-current (I_{ON}) to verify whether each difference between the indexes is within a preset tolerance. Through the verification, it is possible to determine whether the LUT data reflects operating characteristics of the original semiconductor device in a sufficiently accurate manner, and when the reference is not satisfied, the LUT data may be regenerated by adjusting an extraction condition or a sampling resolution of the LUT data.

Accordingly, the extraction unit 100 may not only generate the LUT data through the simulation on the original semiconductor device, but also verify whether the operation of the model based on the LUT data is substantially identical to the operation of the original device in advance, thereby improving reliability of the subsequent retarget and model update processes performed by the retarget unit 200 and the update unit 300.

The retarget unit 200 may generate retarget LUT data by adjusting the LUT data to satisfy a target electrical characteristic index provided by a user.

The retarget unit may generate the retarget LUT data by adjusting the LUT data such that a threshold voltage (Vₜₕ), subthreshold swing (SS), and an on-current (I_{ON}) of the electrical characteristic index are equal to a target threshold voltage, target subthreshold swing, and a target on-current of the target electrical characteristic index, respectively. In other words, the retarget unit 200 may convert the LUT data in stages such that parameters that define main electrical performance of the device, such as the threshold voltage (Vₜₕ), the subthreshold swing (SS), and the on-current (I_{ON}), may satisfy target values provided by the user.

In more detail, the retarget unit 200 may receive target an electrical characteristic index including a target threshold voltage, target subthreshold swing, and a target on-current from the user. Such input values may represent target values intended to reflect subsequent circuit designs or process variations with respect to performance of the original semiconductor device. The retarget unit 200 may calculate an adjustment amount of the LUT data by comparing the target electrical characteristic index with the electrical characteristic index of the original semiconductor device.

According to one embodiment, the retarget unit 200 may generate the retarget LUT data based on a gate-source voltage (V_{GS}) and a drain current (I_{D}) of the LUT data extracted by the extraction unit 100.

For example, the retarget LUT data may be generated by horizontally shifting a curve of the drain current according to the gate-source voltage (I_{D}-V_{GS}) of the LUT data such that the threshold voltage (Vₜₕ) of the electrical characteristic index may be equal to the target threshold voltage (Vₜₕ) of the target electrical characteristic index. In more detail, a difference between the threshold voltage (Vₜₕ) measured at a point corresponding to a reference current (e.g., 100 nA×W/L) on the I_{D}-V_{GS} curve and the target threshold voltage (Vₜₕ) may be calculated, and a voltage shift amount corresponding to the difference may be identically applied to all V_{GS} data in the LUT data. Accordingly, the retarget LUT data may be generated by shifting the entire LUT data to the left and right by a predetermined amount, and the retarget LUT may satisfy the target threshold voltage (Vₜₕ).

Alternatively, the retarget LUT data may be generated by adjusting an angle of a subthreshold region in a graph of the drain current according to the gate-source voltage (I_{D}-V_{GS}) of the LUT data such that the subthreshold swing (SS) of the electrical characteristic index may be equal to the target subthreshold swing (SS) of the target electrical characteristic index. In more detail, since the subthreshold swing (SS) is determined by an angle of log(I_{D})-V_{GS}, the retarget unit 200 may perform the adjustment by scaling an I_{D} value in the subthreshold region by a predetermined ratio so that the angle of the curve matches the target subthreshold swing. Accordingly, the retarget LUT data may be generated by adjusting the LUT data, and the retarget LUT data may satisfy the target subthreshold swing (SS). The above process may be independently performed, separating the subthreshold region to avoid interference with the adjustment of the threshold voltage.

Alternatively, the retarget LUT data may be generated by adjusting a current level of a saturation region in a graph of the drain current according to the gate-source voltage (I_{D}-V_{GS}) of the LUT data such that the on-current of the electrical characteristic index may be equal to the target on-current of the target electrical characteristic index. In other words, the on-current (I_{ON}) may be adjusted in the saturation region, and a ratio between the on-current (I_{ON}) and the target on-current (I_{ON}) may be calculated based on the I_{D} value in a V_{GS} section (e.g., a condition of V_{GS}=V_{DD}) in which the on-current (I_{ON}) is defined, thereby uniformly scaling a current value in the saturation region. Accordingly, the entire current level in the saturation region may be increased or decreased, and the retarget LUT data capable of forming a new curve that precisely reflects a value of the target on-current (I_{ON}) may be generated.

According to one embodiment, the retarget LUT data may be generated by adjusting data between a linear region and a saturation region in a graph of the drain current according to the gate-source voltage (I_{D}-V_{GS}) of the LUT data through interpolation. Accordingly, a discontinuous change in the angle of the curve in the retarget LUT data may be prevented, and physical continuity of the entire I_{D}-V_{GS} curve and stability of the device model may be ensured.

The update unit 300 may determine a final semiconductor device model by comparing an operation simulation result of a model based on the retarget LUT data with the target electrical characteristic index.

In more detail, the update unit 300 may perform SPICE simulation based on the retarget LUT data generated by the retarget unit 200, and determine whether the simulation result satisfy the target electrical characteristic index provided by the user, thereby determining whether to finalize the final semiconductor device model. In other words, the update unit 300 may perform validity verification and quality assurance of the retarget LUT data so as to ensure reliability of a LUT-based device model.

According to one embodiment, the update unit 300 may receive the retarget LUT data from the retarget unit 200, and convert the received retarget LUT data into a model file format that is directly interpretable by the SPICE simulator. Since a LUT file is generally difficult or inefficient to be directly applied in a traditional SPICE netlist format, the update unit 300 may convert the retarget LUT data into a Verilog-A-based model (retarget.va). The above conversion process may be implemented to operate similar to an analog device in the SPICE simulator by expressing gate voltage-current data, capacity data, charge data, and the like in the retarget LUT data as continuous model functions.

The converted Verilog-A model may run in a SPICE environment, and the update unit 300 may perform simulation of the retarget LUT-based model. Since the simulation is performed by applying the same conditions (e.g., V_{DS} sweep, V_{GS} sweep, a temperature condition, etc.) as the simulation performed on the original semiconductor device model, accurate evaluation of whether a retarget model maintains physical consistency and stability as an actual device model may be performed.

The update unit 300 may analyze all output data such as the I_{D}-V_{GS} curve, a subthreshold region characteristic, and a saturation region characteristic, which are output as results of the SPICE simulation, so as to determine whether the values satisfy the target electrical characteristic indexes (Vₜₕ, SS, I_{ON}, etc.) specified by the user within a reference range. For example, it may be determined whether the threshold voltage calculated from the simulation result of the retarget LUT-based model and the target threshold voltage are within a tolerance range. In addition, for example, it may be determined whether the subthreshold swing calculated from the simulation result of the retarget LUT-based model matches the target subthreshold swing. In addition, it may be determined whether the current level of the saturation region in the I_{D}-V_{GS} graph calculated from the simulation result of the retarget LUT-based model satisfies the target on-current (I_{ON}).

When a difference between the operation simulation result of the model based on the retarget LUT data and the target electrical characteristic index is outside a reference range, the update unit 300 may request the retarget unit to regenerate the retarget LUT data, and repeatedly perform this process. The repetitive process may be performed until the retarget LUT data satisfies the target electrical characteristic index, which may effectively address nonlinear interactions that may arise from simultaneous adjustment of multiple characteristics (Vₜₕ, SS, and I_{ON}).

Conversely, when the difference between the operation simulation result of the model based on the retarget LUT data and the target electrical characteristic index is within the reference range, the update unit may determine the model based on the retarget LUT data as the final semiconductor device model. The determined model may be stored as a Verilog-A-based SPICE model, which may be subsequently used directly by a circuit designer or a system developer in a SPICE simulation environment.

Hereinafter, specific experimental examples will be described.

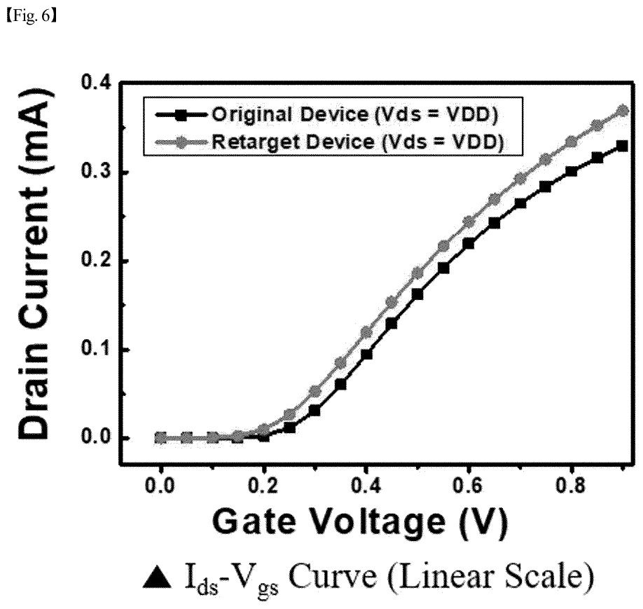

FIG. 6 is a view for comparing I_{DS}-V_{GS} curves of an original device and a retarget device on a linear scale.

Referring to FIG. 6, it may be found that a retarget device generated through a retargeting algorithm may be compared with an I-V characteristic of an original device (GAA 3 nm, a Berkeley short-channel IGFET model for common multi-gate (BSIM-CMG) model) under the same operating condition (V_{DS}=V_{DD}).

In more detail, the original device may have characteristics of Vₜₕ=0.162 V, SS=64.8 mV/dec, and I_{ON}=3.10 mA. Meanwhile, it may be found that as a result of performing LUT-based correction by inputting target values (Vₜₕ=0.142 V, SS≈62 mV, and I_{ON}=3.72 mA) set by the retarget unit, the retarget device exhibits an error rate of less than 1% based on a target characteristic, has a curve shifted to the right as compared to an original curve, and exhibits an increased current level for each section.

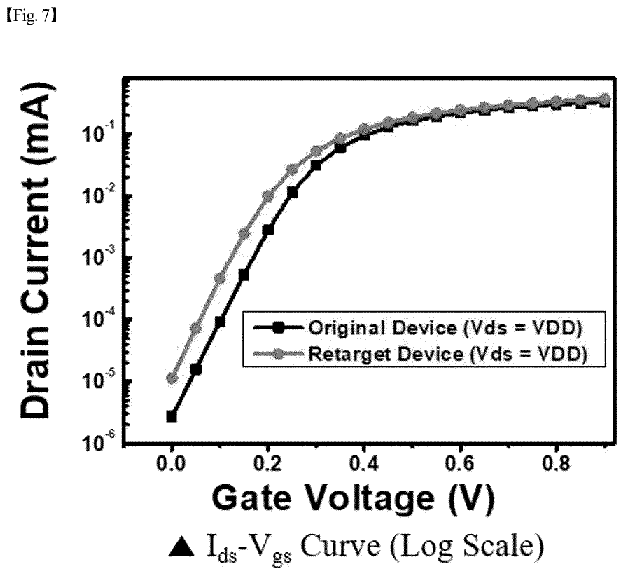

FIG. 7 is a graph for comparing the I_{DS}-V_{GS} curves of the original device and the retarget device on a log scale.

Referring to FIG. 7, it may be found that a current increase section of the retarget device in the subthreshold region is shifted to the left as compared to the original device. This is a result of accurately reflecting a Vₜₕ decrease amount (≈-0.02 V) set by the retarget unit.

In addition, a curve on a log scale in FIG. 7 clearly shows that the subthreshold swing (SS) has been adjusted to match a target value (about 62 mV/dec). In other words, while the SS of the original device was 64.8 mV/dec, an angle of a subthreshold curve in the retarget LUT has been adjusted so as to allow an error from the target characteristic to successfully converge to less than 1%. In addition, it may be found that a current of the retarget device even in the saturation region is also increased as compared to the original device so as to satisfy a target level of I_{ON}=3.72 mA.

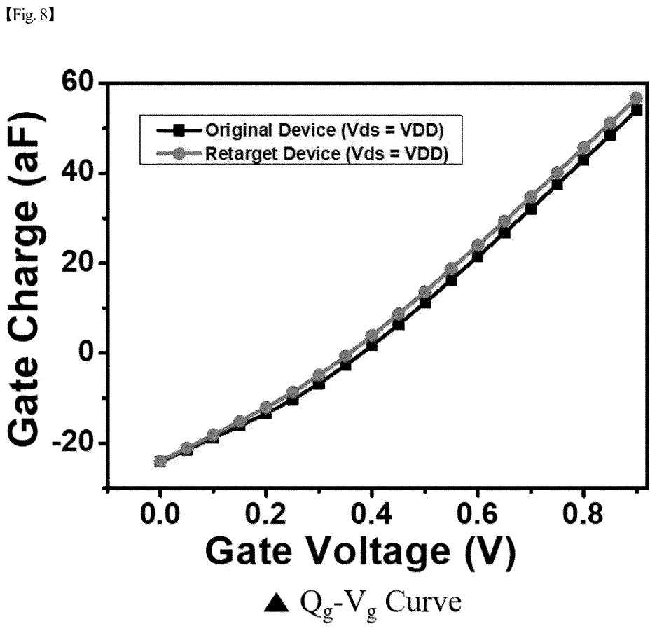

FIG. 8 is a graph for comparing Q_{g}-V_{g} curves of the original device and the retarget device.

Referring to FIG. 8, it may be found that a characteristic of a gate charge (Q_{g}) according to a gate voltage change is reproduced in the retarget device almost identically to the original device. The extraction unit may extract a Q_{g} variation, a Q_{d} variation, and the like based on a V_{GS} shift from a LUT by using a devltrand variable supported by the BSIM-CMG model. Thereafter, in a retarget step, a set Vₜₕ shift (−0.1 V) may be identically applied to Q_{g}-V_{g} data so as to perform voltage conversion. The retargeted Q_{g} may be reproduced with an error rate of less than 1% as compared to a target value, which shows that charge characteristic adjustment that has required significant time and labor with an existing BSIM parameter fitting scheme may be accurately performed with only a LUT-based scheme.

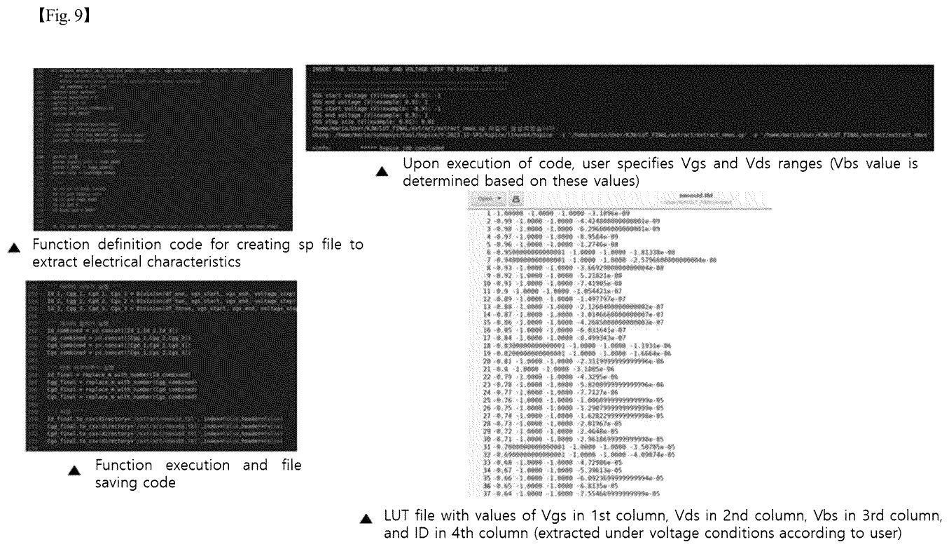

FIG. 9 is a view for describing a process of automatically generating a SPICE input file (sp file) for extracting an electrical characteristic according to an embodiment of the present invention.

Referring to FIG. 9, it may be found that for an original semiconductor device including a GAA-based BSIM-CMC model, the extraction unit automatically generates a SPICE simulation input file based on a gate-source voltage (V_{GS}) range and a drain-source voltage (V_{DS}) range specified by the user.

In detail, a code example on the left of FIG. 9 shows a state in which a function of automatically creating a simulation file including a SPICE instruction (.option, .measure, .print, etc.) and a device model call (.include) is defined. In addition, it may be found that V_{GS} and V_{DS} sweep conditions are automatically reflected in a code, and a body-source voltage (V_{BS}) is automatically calculated according to a voltage range that is input by the user. On the lower right of FIG. 9, a process of storing V_{GS}, V_{DS}, V_{BS}, and I_{D} values for each column in a LUT file (nmosId.tbl, etc.) generated after the function is executed is shown, which is used as base data for a process of generating a LUT-based model according to the present invention.

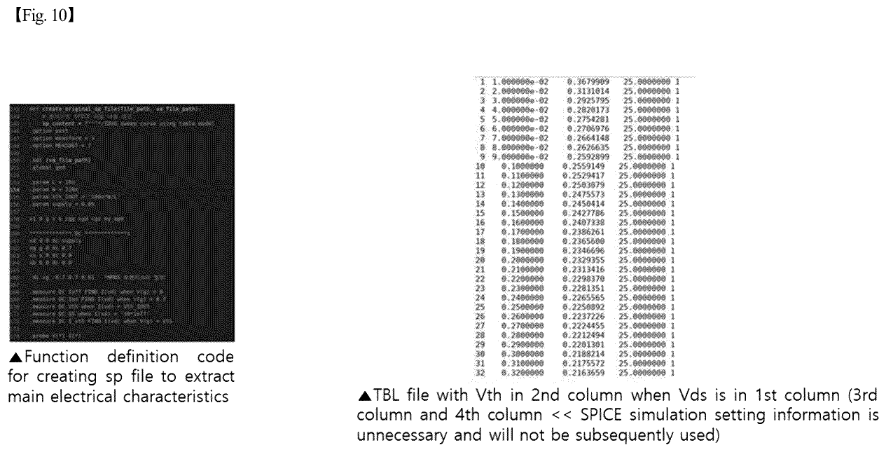

FIG. 10 is a view for describing a process of generating a table file (TBL) for extracting a threshold voltage (Vₜₕ) of an original semiconductor device according to an embodiment of the present invention.

Referring to FIG. 10, it may be found that the extraction unit performs SPICE simulation on the original semiconductor device to measure a threshold voltage (Vₜₕ) under each drain voltage (V_{DS}) condition, and saves results thereof in a TBL file format (e.g., vth.tbl).

A SPICE input file generation code on the left of the drawing shows that a measurement instruction (.measure Vth FIND⊚) for measuring the threshold voltage is automatically generated, and only a Vₜₕ value measured under a simulation sweep condition is saved in the form of a first column (V_{DS}) and a second column (Vₜₕ) in a TBL file. It may be found through a TBL example on the right of the drawing that a Vₜₕ value according to a V_{DS} change is organized in the form of a simple table without SPICE setting information, which is used as base data for accurately reflecting a change in a threshold voltage during a retargeting process.

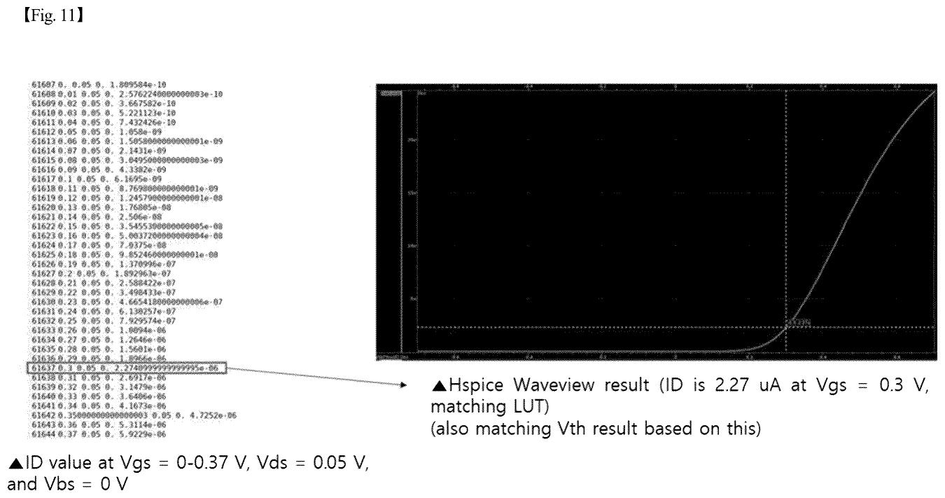

FIG. 11 is a view showing a process of verifying whether LUT data matches a SPICE simulation result according to an embodiment of the present invention.

Referring to FIG. 11, it may be found that a drain current (I_{D}) value corresponding to specific voltage conditions (V_{GS}=0.3 V, V_{DS}=0.05 V, and V_{BS}=0 V) is recorded as 2.27 μA in the LUT file, and a simulation result using HSPICE WaveView under the same conditions also accurately matches I_{D}=2.27 μA. This demonstrates that a LUT generation algorithm according to the present invention generates LUT data that perfectly matches a SPICE solver result using an actual device model (GAA-based BSIM-CMC model), and means that the LUT-based model substantially reproduces a physical operation of an original compact model. In addition, it may be found through FIG. 11 that a threshold voltage (Vₜₕ) calculated from the LUT data is also identical to a WaveView result.

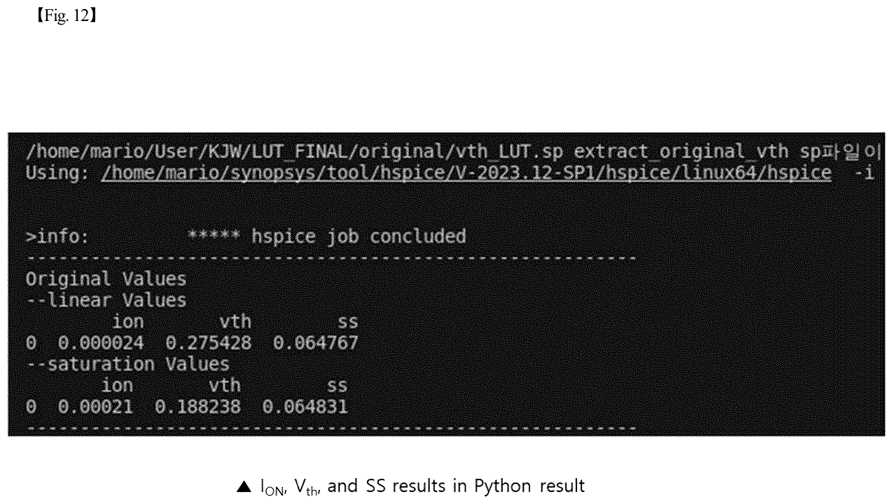

FIG. 12 is a view showing results of extracting main electrical characteristics (Vₜₕ, SS, and I_{ON}) of the original semiconductor device according to an embodiment of the present invention.

Referring to FIG. 12, it may be found that the extraction unit calculates and displays the threshold voltage (Vₜₕ), the subthreshold swing (SS), and the on-current (I_{ON}) under two representative operating conditions, which are the linear region (V_{DS}=0.05 V) and the saturation region (V_{DS}=V_{DD}).

For example, under the linear condition, Vₜₕ≈0.275 V, SS≈64.7 mV/dec, I_{ON}≈2.4×10⁻⁵ A, and the like may be calculated, and under the saturation condition, Vₜₕ≈0.188 V, SS≈64.8 mV/dec, and I_{ON}≈2.1×10₋₄ A may be derived. These values may be subsequently used as reference values for parameter adjustment performed by the retarget unit 200.

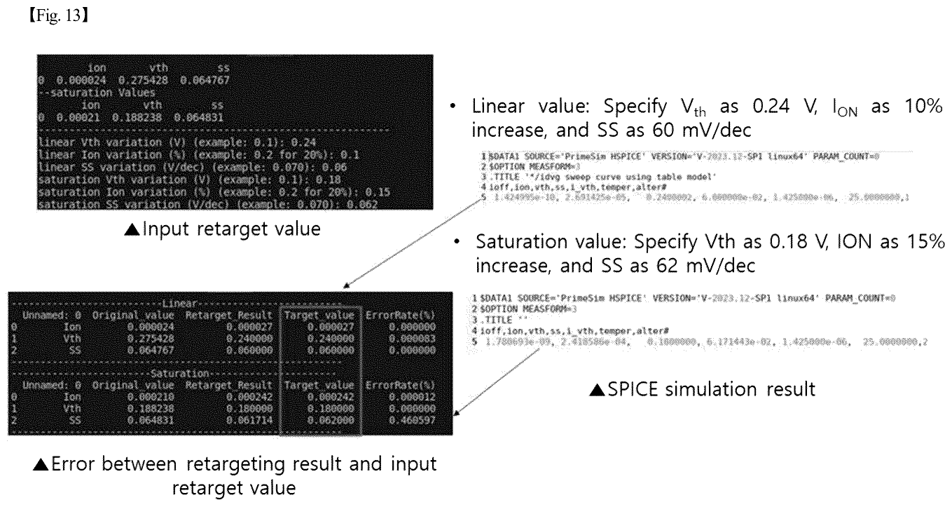

FIG. 13 is a view showing a target electrical characteristic index (retarget value) that is input by a user and a SPICE simulation result obtained accordingly, and error comparison according to an embodiment of the present invention.

Referring to FIG. 13, the user may input target threshold voltage (Vₜₕ), target on-current (I_{ON}), and target SS values for each of the linear and saturation conditions, and the retarget unit 200 may generate LUT data corresponding to the input values. For example, under the linear condition, Vₜₕ=0.24 V, I_{ON}=+10%, and SS=60 mV/dec may be specified, and under the saturation condition, Vₜₕ=0.18 V, I_{ON}=+15%, and SS=62 mV/dec may be specified. It may be found that a SPICE simulation result on the right of the drawing quantitatively shows a difference from these input values, and each characteristic value is adjusted to an error rate of less than 1% so as to satisfy target values in a highly accurate manner.

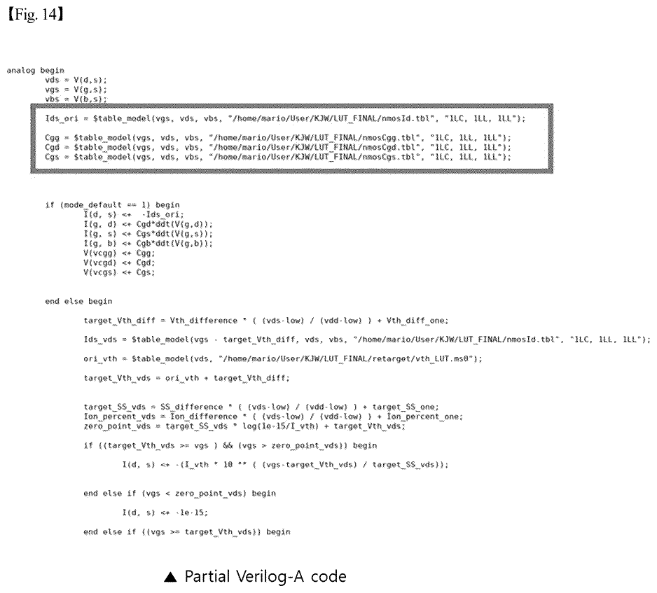

FIG. 14 is a view showing a portion of internal implementation of a Verilog-A device model that operates based on retarget LUT data according to an embodiment of the present invention.

Referring to FIG. 14, data of a LUT file (e.g., nmosId.tbl, nmosCgg.tbl, nmosCgd.tbl, etc.) extracted from the original semiconductor device may be inserted in a beginning portion of a Verilog-A model in the form of a table model, and a process of converting the LUT data according to retarget purposes through a conditional statement and an arithmetic expression may be subsequently implemented. It may be found that a Vₜₕ shift expression, a SS scaling expression, and a I_{ON} scaling expression vary according to a voltage range (V_{DS} low/high), and Verilog-A is configured to ensure that a LUT-based current and charge model operates like an actual device. This shows that a retarget expression proposed in the present invention are automatically applied at a model level.

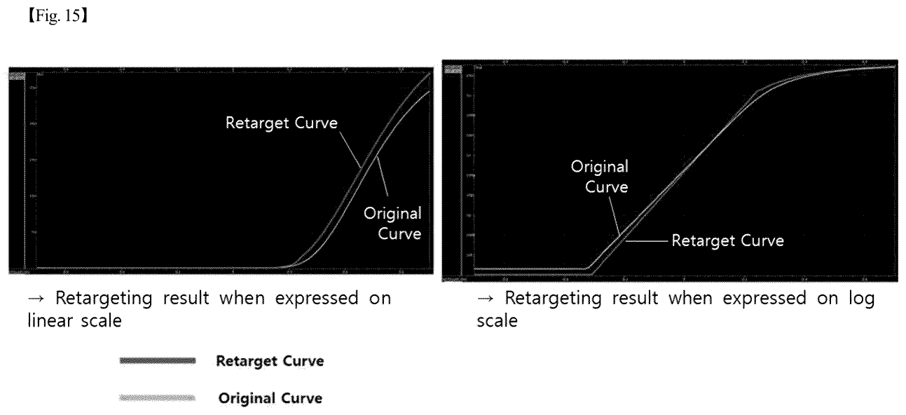

FIG. 15 is a view showing results of displaying an I_{D}-V_{GS} curve of a retargeted device model on a linear scale and a log scale according to an embodiment of the present invention.

Referring to FIG. 15, it may be found that a retargeted curve (Retarget Curve) clearly satisfies target characteristics (Vₜₕ↓, I_{ON}↑, and SS↓) specified by the user as compared to a curve of an original device (Original Curve), with a reduced threshold voltage, an increased on-current, and a reduced angle in the subthreshold region. In particular, an increase in a current amount in an upper saturation region is clearly shown on a linear scale, and a change in a subthreshold angle and a shift in a threshold voltage are clearly shown on a log scale, so that a retargeting effect may be visually verified.

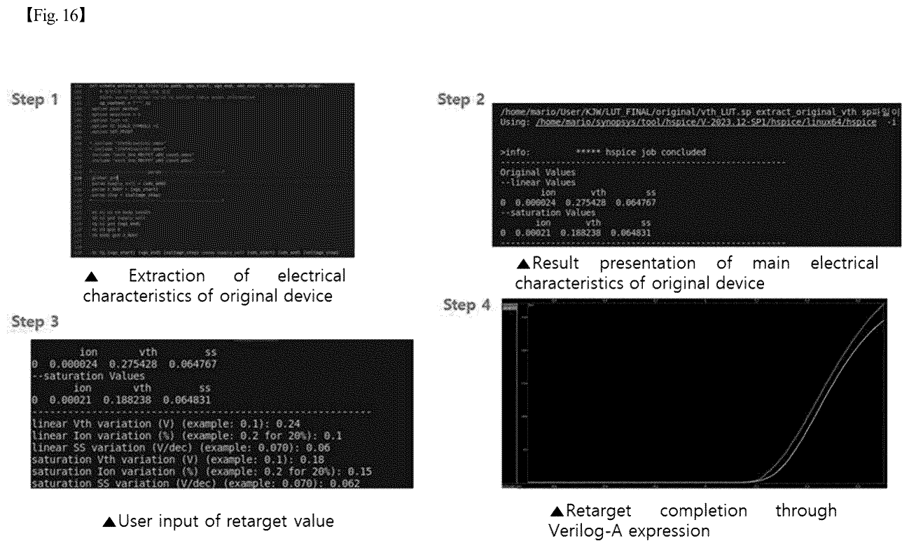

FIG. 16 is a view for describing a procedural flow of a process for generating a semiconductor device model according to an embodiment of the present invention.

Referring to FIG. 16, it may be found that the present invention is performed by the following steps. Original device electrical characteristic extraction step (Step 1): SPICE input file creation→simulation execution→LUT data generation according to voltage conditions. Main electrical characteristic index (Vₜₕ, SS, and I_{ON}) calculation step (Step 2): Electrical indexes are calculated in linear and saturation regions. Retarget target value input step (Step 3): A user provides a target Vₜₕ, target SS, and a target I_{ON}. Verilog-A-based retarget model generation and verification step (Step 4): Retarget expression application→simulation execution→final model determination when target indexes are satisfied.

Although the exemplary embodiments of the present invention have been described in detail above, the scope of the present invention is not limited to a specific embodiment, and shall be interpreted by the appended claims. In addition, it is to be understood by a person having ordinary skill in the art that various changes and modifications can be made without departing from the scope of the present invention.

What is claimed is:

1. A system for generating a semiconductor device model, the system comprising:
an extraction unit for extracting LUT data including input data and output data of an original semiconductor device by simulating the original semiconductor device under various operating conditions, and calculating an electrical characteristic index of the original semiconductor device from the LUT data;
a retarget unit for generating retarget LUT data by adjusting the LUT data to satisfy a target electrical characteristic index provided by a user; and
an update unit for determining a final semiconductor device model by comparing an operation simulation result of a model based on the retarget LUT data with the target electrical characteristic index.

2. The system of claim 1, wherein the LUT data includes the input data and the output data in a form of a look-up table.

3. The system of claim 2, wherein the retarget unit generates the retarget LUT data by adjusting the LUT data such that a threshold voltage (Vₜₕ), a subthreshold swing (SS), and an on-current (I_{ON}) of the electrical characteristic index are equal to a target threshold voltage, target subthreshold swing, and a target on-current of the target electrical characteristic index, respectively.

4. The system of claim 3, wherein the retarget LUT data is generated based on a gate-source voltage (V_{GS}) and a drain current (I_{D}) of the LUT data.

5. The system of claim 4, wherein the retarget LUT data is generated by horizontally shifting a curve of the drain current according to the gate-source voltage (I_{D}-V_{GS}) of the LUT data such that the threshold voltage of the electrical characteristic index is equal to the target threshold voltage of the target electrical characteristic index.

6. The system of claim 4, wherein the retarget LUT data is generated by adjusting an angle of a subthreshold region in a graph of the drain current according to the gate-source voltage (I_{D}-V_{GS}) of the LUT data such that the subthreshold swing of the electrical characteristic index is equal to the target subthreshold swing of the target electrical characteristic index.

7. The system of claim 4, wherein the retarget LUT data is generated by adjusting a current level of a saturation region in a graph of the drain current according to the gate-source voltage (I_{D}-V_{GS}) of the LUT data such that the on-current of the electrical characteristic index is equal to the target on-current of the target electrical characteristic index.

8. The system of claim 4, wherein the retarget LUT data is generated by adjusting data between a linear region and a saturation region in a graph of the drain current according to the gate-source voltage (I_{D}-V_{GS}) of the LUT data through interpolation.

9. The system of claim 1, wherein the update unit determines the model based on the retarget LUT data as the final semiconductor device model when a difference between the operation simulation result of the model based on the retarget LUT data and the target electrical characteristic index is within a reference range.

10. The system of claim 9, wherein the update unit requests the retarget unit to regenerate the retarget LUT data when the difference between the operation simulation result of the model based on the retarget LUT data and the target electrical characteristic index is outside the reference range.

11. A system for generating a semiconductor device model, the system comprising:
an extraction unit for extracting LUT data including input data and output data of an original semiconductor device by simulating the original semiconductor device under various operating conditions, calculating an electrical characteristic index of the original semiconductor device from the LUT data, and verifying whether an operation of a model based on the LUT data matches an operation of the original semiconductor device;
a retarget unit for generating retarget LUT data by adjusting the LUT data to satisfy a target electrical characteristic index provided by a user; and
an update unit for determining a final semiconductor device model by comparing an operation simulation result of a model based on the retarget LUT data with the target electrical characteristic index.

12. The system of claim 11, wherein simulation of the original semiconductor device and an operation simulation of the model based on the retarget LUT data are performed through simulation program with integrated circuit emphasis (SPICE).

13. The system of claim 12, wherein the retarget LUT data is converted into a Verilog-A-based model and applied to SPICE simulation.

14. A method for generating a semiconductor device model, the method comprising:
extracting LUT data including input data and output data of an original semiconductor device by simulating the original semiconductor device under various operating conditions;
calculating an electrical characteristic index of the original semiconductor device from the LUT data;
generating retarget LUT data by adjusting the LUT data to satisfy a target electrical characteristic index provided by a user; and
determining a final semiconductor device model by comparing an operation simulation result of a model based on the retarget LUT data with the target electrical characteristic index.

15. The method of claim 14, wherein the LUT data includes the input data and the output data in a form of a look-up table, and
the electrical characteristic index includes a threshold voltage (Vₜₕ), a subthreshold swing (SS), and an on-current (I_{ON}).
